(19) United States
(12) Patent Application Publication
(10) Pub. No.: US 2001/0050040 A1
(43) Pub. Date: Dec. 13, 2001

(54) Diaphragm and reciprocating pump using the same

(76) Inventor: Toshiharu Shimizu, Ikuno-cho (JP)

Correspondence Address: FULBRIGHT & JAWORSKI L.L.P., 29th Floor, 865 South Figueroa Street, Los Angeles, CA, 90017, US

(21) Appl. No.: 09/865,834

(22) Filed: May 25, 2001

(30) Foreign Application Priority Data
May 25, 2000 (JP) 2000-155034

(51) Int. Cl. C30B 1/00

(52) U.S. Cl. 117/200

(57) ABSTRACT

A diaphragm is integrally formed with a movable section and a perimeter section. The movable section is adapted to be reciprocally moved, and the perimeter section is disposed around the movable section and shaped to provide a clamp receiving portion adapted to be clamped into a fixed position. A bending portion along which the movable section is reciprocally moved with the clamp receiving portion clamped is located closer to the movable section than the clamp receiving portion of the perimeter section.

### BACKGROUND OF THE INVENTION

1. Field of the Invention

The present invention relates to a diaphragm and a reciprocating pump using the same, particularly a highly durable diaphragm suitable for transferring slurry therethrough and a reciprocating pump using the same, and more particularly a reciprocating pump suitable for pumping slurry used for a chemical mechanical polishing (CMP) of wafers in electronic materials.

2. Discussion of the Background

There is known a reciprocating pump of the type that has a piston unit as a movable part in which a diaphragm is mounted. It is customary that the diaphragm of such a reciprocating pump is made of a material possessing excellent wear resistance and corrosion resistance. The reciprocating pump of this type has a leakage-free structure in the reciprocally movable part thereof, and is provided at inlet and outlet sides thereof with ball valves acting as check valves.

The reciprocating pump with the diaphragm having excellent wear resistance and corrosion resistance, which has the leak-free structure, is applicable to transferring not only clear water but also a solid material (e.g., particulate material) containing liquid or slurry.

In order to transfer the slurry, the reciprocating pump of the type that includes the diaphragm is sometimes employed.

An example of the structures which conventionally known reciprocating pumps employ is illustrated in FIG. 4, which is a schematically cross sectional view illustrating particularly a pump head and its proximity. The reciprocating pump in this Figure is designed to transfer the slurry from an inlet 103 to an outlet 104 through actuation of a piston unit 102 and hence reciprocal movement or axial deflection of the diaphragm 101. A check ball 105 is disposed above the inlet 103, while a check ball 106 is disposed below the outlet 104.

The diaphragm 101 as illustrated in FIG. 4 has a perimeter section 101a which is clamped into a fixed position by a fixed member 111 and a pressing member 112. FIG. 5 illustrates an enlarged view illustrating the fixed portion of the diaphragm 101 encircled by dotted line Y in FIG. 4.

According to the thus arranged conventional reciprocating pump, a movable section making up a central part of the diaphragm 101 (or, a portion other than the clamped portion or the perimeter section 101a) is reciprocally moved or axially deflected. To avoid the occurrence of the leakage between the perimeter section 101a and the diaphragm pressing member 112, some measurements must be taken. In this respect, the diaphragm 101 of the conventional reciprocating pump is rigidly secured in position to cause no clearance between the diaphragm fixed member 111, the perimeter section 101a and the diaphragm pressing member 112, as illustrated in FIG. 5.

However, the thus arranged conventional diaphragm and reciprocating pump pose a problem as described below.

The diaphragm 101 as an essential part of the reciprocating pump is secured in position with the perimeter section 101a thereof clamped by using the diaphragm fixed member 111 and the diaphragm pressing member 112, as described above. This tight clamping must be done for the reason that, if there is a clearance between the diaphragm 101, the fixed member 111 and the pressing member 112, the slurry or the like may intrude into the clearance under the reciprocal motion or axial deflection of the diaphragm 101. This may cause undesirable effects on the life of the diaphragm 101 and its associated parts. Therefore, the fixed member 111 and the pressing member 112 together tightly clamp the diaphragm 101 through their end portions 111b and 112b with causing no clearance to the diaphragm 101. The portion of the diaphragm 101 clamped by the fixed member 111 and the pressing member 112 through their end portions 111b and 112b will hereinafter be referred to a clamp receiving portion 101b.

With the rigidly secured clamp receiving portion, the slurry or the like is unlikely to intrude into the interface of the diaphragm against the fixed member 111 and the pressing member 112 when the diaphragm 101 is in a stationary state. However, when the diaphragm 101 is driven through the motion of the piston unit 102, it is reciprocally moved or axially deflected along the clamp receiving portion 101b. The clamp receiving portion 101b is thus repeatedly bent, so that there may cause a clearance between the diaphragm 101, and the fixed member 111 and the pressing member 112.

Therefore, there remains a possibility of causing a clearance between the clamp receiving portion 101b of the diaphragm 101 and the end portion 112b of the pressing member 112 due to the repeated bending of the clamp receiving portion 101b in the conventional reciprocating pump. Accordingly, the slurry or any other fluids passing the diaphragm 101 may intrude into this clearance, causing excessive friction between the diaphragm 101 and the pressing member 112. This may pose a problem of shortening the life of the diaphragm 101 and its associated parts, or causing any other undesirable effects on the diaphragm 101. Specifically, where a bending portion around which the diaphragm 101 is reciprocally moved or axially deflected is located at the portion rigidly clamped for prevention of the leakage, or closer to the same, the bending stress is amplified. As a result, there causes an undesirable effect on the life of the diaphragm 101 and its associated parts and hence deterioration in durability of the diaphragm 101 and its associated parts. That is, the excessive friction of the diaphragm 101 against the pressing member 112 leads to a crack or rupture of the diaphragm 101, deteriorating the durability of the diaphragm 101. As a result of the deterioration of the diaphragm, it must be frequently replaced with a new one.

In consideration of the above, it is an object of the present invention to provide a diaphragm that has an improved durability against the bending stress repeatedly applied, with the fluid being in contact with the diaphragm. It is another object of the present invention to provide a reciprocating pump that possesses an improved durability against the repeatedly applied bending stress, by the use of this diaphragm and is therefore capable of reducing the number of operation times for the replacement of the diaphragm.

### SUMMARY OF THE INVENTION

According to one aspect of the present invention, there is provided a diaphragm integrally formed with a movable section and a perimeter section. The movable section is adapted to be reciprocally moved, and the perimeter section is disposed around the movable section and shaped to provide a clamp receiving portion adapted to be clamped into a fixed position. A bending portion along which the movable section is reciprocally moved with the clamp receiving portion clamped is located closer to the movable section than the clamp receiving portion of the perimeter section.

With the above arrangement, the diaphragm is not bent at the clamp receiving portion of the perimeter section but a portion closer to the movable section than this clamp receiving portion. Therefore, the diaphragm is unlikely to be influenced by the positional variation due to the bending of the diaphragm, so that amplification of the bending stress during the reciprocal movement of the diaphragm and hence the occurrence of rupture, crack or the like of the diaphragm can effectively be reduced. As a result, an improved durability of the diaphragm is attainable.

According to another aspect of the present invention, there is provided a diaphragm integrally formed with a movable section and a perimeter section used in a pump or the like for pumping fluid therethrough. The movable section is adapted to be reciprocally moved for creating a pumping effect, and the perimeter section is disposed around the movable section and shaped to provide a clamp receiving portion adapted to be clamped into a fixed position. A bending portion along which the movable section is reciprocally moved with the clamp receiving portion clamped is located closer to the movable section than the clamp receiving portion of the perimeter section.

With the above arrangement, the diaphragm is not bent at the clamp receiving portion of the perimeter section but a portion closer to the movable section than this clamp receiving portion. Thus, it is unlikely that the diaphragm is influenced by the positional variation due to the bending of the diaphragm, so that there causes no clearance between a member for clamping the perimeter section and the perimeter section. Accordingly, the fluid is unlikely to intrude into the interface between the clamp receiving portion of the perimeter section and the clamping member, thereby effectively preventing the occurrence of rupture, crack or the like of the diaphragm, and attaining an improved durability of the diaphragm against the reciprocal movement thereof in contact with the fluid transferred. Also, according to the present invention, the dislocation of the bending portion away from the clamp receiving portion can effectively omit the possibility of amplifying the maximum stress unlike the conventional arrangement, and hence reduce the maximum stress.

The clamp receiving portion of the perimeter section is preferably formed to have a higher rigidity than the bending portion. With this higher rigidity, the clamp receiving portion of the perimeter section is hardly bent, thereby preventing the fluid from intruding into the interface between the clamp receiving portion of the perimeter section and the clamping member. Thus, the rupture, crack or the like of the diaphragm may effectively be prevented, and an improved durability against the repeatedly applied bending stress, with the fluid being in contact with the diaphragm, can be attained.

The perimeter section is preferably made of a material having a higher rigidity than the movable section. With this structure, the clamp receiving portion of the perimeter section can attain a higher rigidity, thereby easily achieving the desirable effect mentioned above.

The clamp receiving portion of the perimeter section is preferably formed to be thicker than the bending portion in the reciprocating or axial direction of the movable section. With this structure, the clamp receiving portion of the perimeter section can attain a higher rigidity, so that the clamp receiving portion is unlikely to bend. As a result, the fluid is prevented from intruding into the interface between the clamp receiving portion of the perimeter section and the clamping member. Thus, the rupture, crack or the like of the diaphragm may effectively be prevented, and an improved durability against the repeatedly applied bending stress, with the fluid being in contact with the diaphragm, can be attained.

The movable section and the perimeter section preferably have a multilayered structure with layers thereof deposited to each other in the reciprocating axial direction or axial direction of the movable section, in which at least one of the layers is adjusted in rigidity so that the clamp receiving portion of the perimeter section has a higher rigidity than the bending portion.

The movable section and the perimeter section also preferably have a multi-layered structure with layers thereof deposited to each other in the reciprocating direction or axial direction of the movable section, in which at least one of the layers is adjusted in thickness so that the clamp receiving portion of the perimeter section has a higher rigidity than said bending portion.

The movable section and the perimeter section also preferably have a multi-layered structure with layers thereof deposited to each other in the reciprocating direction or axial direction of the movable section, in which at least one of the layers is adjusted in thickness so that the clamp receiving portion of the perimeter section is thicker than the bending portion.

According to still another aspect of the present invention, there is provided a reciprocating pump that includes a reciprocally movable diaphragm. The diaphragm is integrally formed with a movable section and a perimeter section. The movable section is adapted to be reciprocally moved for creating a pumping effect, and the perimeter section extends around the movable section to provide a clamp receiving portion adapted to be clamped into a fixed position. A pressing member and a fixed member are provided to cooperate with each other to clamp the clamp receiving portion of the perimeter section into a fixed position. A bending portion, along which the movable section is reciprocally moved or axially deflected with said clamp receiving portion clamped between the pressing member and the fixed member, is located closer to the movable section than the clamp receiving portion of the perimeter section.

The reciprocating pump is preferably constructed by using a diaphragm having various structures as mentioned above.

### BRIEF DESCRIPTION OF THE DRAWINGS

The above, and other objects, features and advantages of the present invention will become apparent from the detailed description thereof in conjunction with the accompanying drawings wherein.

FIG. 1 is a schematic cross section illustrating a pump head and its proximity of a reciprocating pump according to a first embodiment of the present invention.

FIG. 2 is an enlarged view of a portion of the pump encircled by dotted lines X in FIG. 1.

FIG. 3 is an enlarged cross section illustrating a pump head and its proximity of a reciprocating pump according to a second embodiment of the present invention.

FIG. 4 is a schematic cross section illustrating a pump head and its proximity of a conventional reciprocating pump.

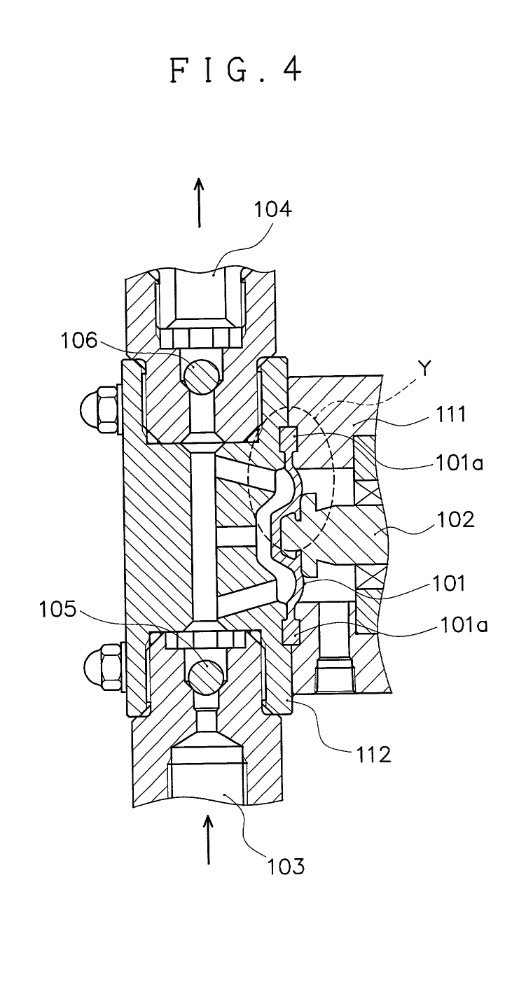

FIG. 5 is an enlarged view illustrating a portion of the pump encircled by dotted lines Y in FIG. 4.

### DETAILED DESCRIPTION OF THE PREFERRED EMBODIMENT

The embodiments of the present invention will be hereinafter described with reference to the drawings attached hereto.

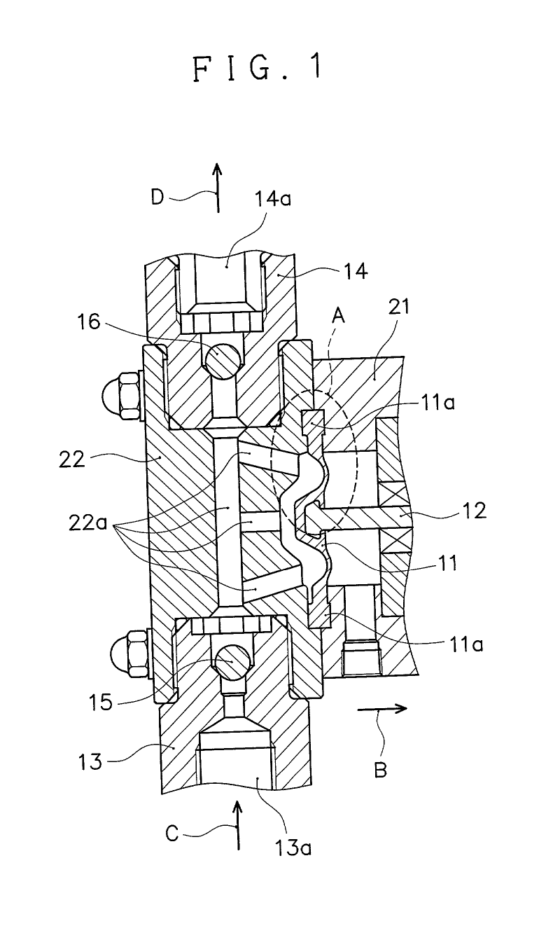

FIG. 1 is a schematic cross section illustrating a pump head and its proximity of a reciprocating pump according to the first embodiment of the present invention. The reciprocating pump as illustrated herein is designed to transfer slurry, particularly CMP slurry used in the CMP process for wafers in electronic materials. The CMP slurry herein referred is meant, but not limited to have a concentration of 5 to 50 wt % and a maximum aggregate particle size of 10 μm or less. As a component or components of the slurry, a cerium component, alumina component, zirconia component or manganese dioxide component is solely used, or the admixture thereof is used.

The reciprocating pump as illustrated in FIG. 1 includes a diaphragm 11 which is reciprocally moved or axially deflected to transfer the slurry through an inlet 13a formed in a first joint 13 towards an outlet 14a formed in a second joint 14. A driving device (not shown) for driving a piston unit 12 is not limited to a specific one. Rather, a varying type of the driving device such as a mechanical, pneumatic, hydraulic, electric, or magnetic type of the driving device may be employed. Also, the driving device may be arranged in direct or indirect communication with the piston unit 12.

The diaphragm 11 is clamped between a pump head 22, and a spacer 21 which is disposed between the driving device (not shown) and the pump head 22. The spacer 21 and the pump head 22 respectively act as a fixed member and a pressing member for clamping the diaphragm into a fixed position. In the following description, the members 21 and 22 will be referred to the fixed member and the pressing member. Thus, the diaphragm 11 is secured in position with a perimeter section 11a and its periphery clamped between the fixed member 21 and the pressing member 22.

The first joint 13 is connected to a slurry feeding means such as a storage tank (not shown) for storing the slurry therein, while the second joint 14 is connected to a slurry receiving member (not shown) in which the slurry is used for a specific purpose. This slurry receiving member may be a polishing cloth (not shown) adapted to be mounted on a polishing table for conducting the CMP. The slurry used for the CMP may be that described above, namely the slurry having a concentration of 5 to 50 wt % and a maximum aggregate particle size of 10 μm or less, while as its component or components, a cerium component, alumina component, zirconia component or manganese dioxide component is solely used, or the admixture thereof is used.

An inlet check ball 15 and an outlet check ball 16 are respectively provided above the inlet 13a and below the outlet 14a.

The pump head 22 forms therein a passageway 22a for transferring the slurry therethrough. In this embodiment, the diaphragm 11 is designed to be moved in the reciprocating direction or the direction of arrow A, so that a negative pressure is generated within the passageway 22a and with respect to the check balls 15 and 16, thereby lifting the inlet check ball 15 in the direction of arrow B, and hence feeding the slurry into the passageway 22a through the inlet 13a. This step will be hereinafter referred to a first transferring step.

The diaphragm of this embodiment is also designed to be moved in the opposite direction to that of the arrow A, so that a positive pressure is generated within the passageway 22a and with respect to the check balls 15 and 16, thereby lifting the outlet check ball 16 in the direction of arrow C, and hence discharging the slurry within the passageway 22a through the outlet 14a. This step will be hereinafter referred to a second transferring step. That is, the reciprocating pump of this embodiment repeatedly conducts the aforesaid first and second transferring steps, or reciprocally moves the diaphragm 11, so that the slurry can be transferred to an intended device or portion.

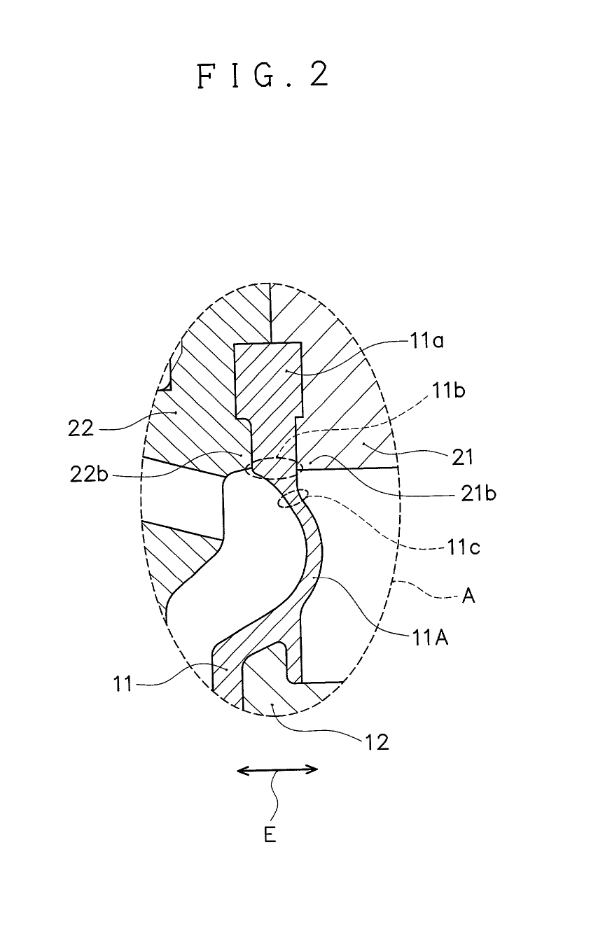

FIG. 2 is an enlarged view of the pump head and its proximity illustrated in FIG. 1, namely a portion encircled by dotted lines X in FIG. 1.

In this embodiment, the diaphragm 11 is clamped into a fixed position by using the fixed member 21 and the pressing member 22, as illustrated in FIG. 1. This arrangement will be now described in detail with reference to FIG. 2. The diaphragm 11 has a perimeter section 11a and its periphery, both being clamped by using the fixed member 21 and the pressing member 22. A portion of the diaphragm 11 closer to a movable section 11A is fixed by an end portion 21b of the fixed member 21 and an end portion 22b of the pressing member 22. The portion which is clamped by the end portion 2lb of the fixed member 21 and the end portion 22b of the pressing member 22 will be hereinafter referred to a clamp receiving portion 11b.

The diaphragm 11 as a constituent member of the reciprocating pump as illustrated in FIGS. 1 and 2 is integrally formed with the movable section 11A and the perimeter section 11a, both of which are formed by using the same material in this embodiment. The diaphragm 11 of this embodiment is also formed so that the clamp receiving portion 11b is larger in thickness than the movable section 11A in the reciprocating direction of the diaphragm 11 or the direction of arrow D in FIG. 2.

With the reciprocating pump using the diaphragm 11 having the above arrangement, the slurry can smoothly be transferred without causing the problems as mentioned above, and therefore the reciprocating pump can be effectively driven.

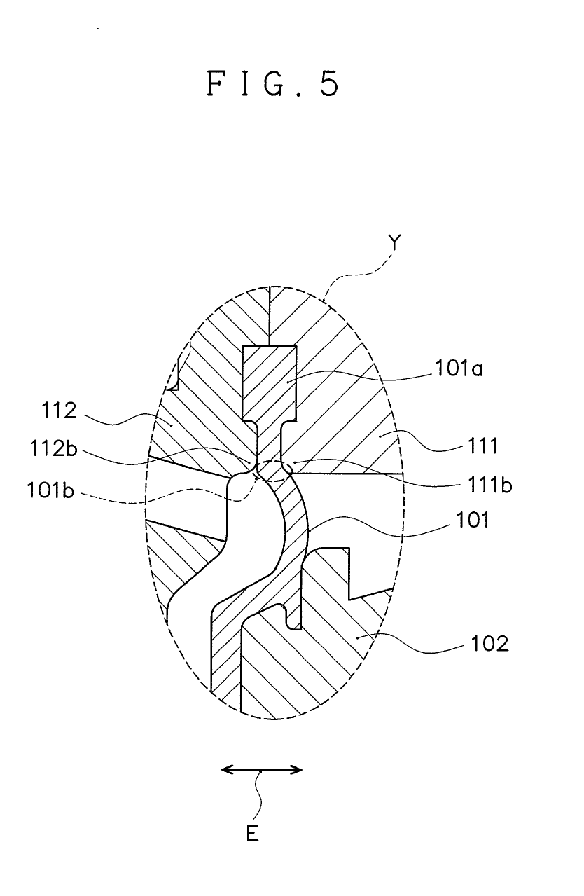

That is, in the conventional reciprocating pumps, there may cause the intrusion of the slurry into the interface between the diaphragm 101 and the pressing member 112 as a result of the repeated application of the bending stress on the clamp receiving portion 101b due to the reciprocal movement of the diaphragm 101, and also may cause the deterioration of the life of the diaphragm 101 and its associated parts due to amplified stress through the bending portion at the time of the reciprocal movement of the diaphragm 101, which bending portion is matched in position with or located closer to the clamped portion which is rigidly clamped for the leakage free arrangement (see FIG. 5). On the contrary, the diaphragm 11 in the reciprocating pump of this embodiment is unlikely to bend along the clamp receiving portion during the reciprocal movement of the piston unit 12 in the direction of arrow D, thus not causing such problems. The diaphragm 11 of the reciprocating pump according to this embodiment is reciprocally moved with a bending portion 11c closer to the movable section 11A than the clamp receiving portion 11b, along which the diaphragm 11 is bent.

The dislocation of the bending portion 11c from the clamp receiving portion 11b is accomplished by the adjustment of the thickness of the diaphragm 11 in the reciprocating direction D. Specifically, the diaphragm 11 is formed with the clamp receiving portion 11b thicker than the movable section 11A, as described above. By this adjustment, the clamp receiving portion 11b has a higher rigidity than the bending portion 11c. The diaphragm 11 of this embodiment is thus driven, as repeatedly bending along the bending portion 11c dislocated from the clamp receiving portion 11b.

More specifically, according to the reciprocating pump of this embodiment with the diaphragm 11 having the clamp receiving portion 11b, which is unlikely to bend during the reciprocal movement of the diaphragm 11, there causes no clearance between the clamp receiving portion 11b and the pressing member 22. Also, the bending portion 11c, which is not matched in position with the clamp receiving portion 11b, enables the maximum stress applied on the diaphragm 11 to be reduced. Thus, the reciprocating pump can transfer the slurry through the reciprocal movement of the diaphragm 11 and more specifically the movable section 11A with no clearance as mentioned above, thereby effectively preventing the slurry from intruding into the interface between the clamp receiving portion 11b and the pressing member 22. As a result, excessive friction or any other undesirable effects due to the intrusion of the slurry is avoidable, the occurrence of cracks, ruptures and so on can be limited and hence an improved durability is attainable.

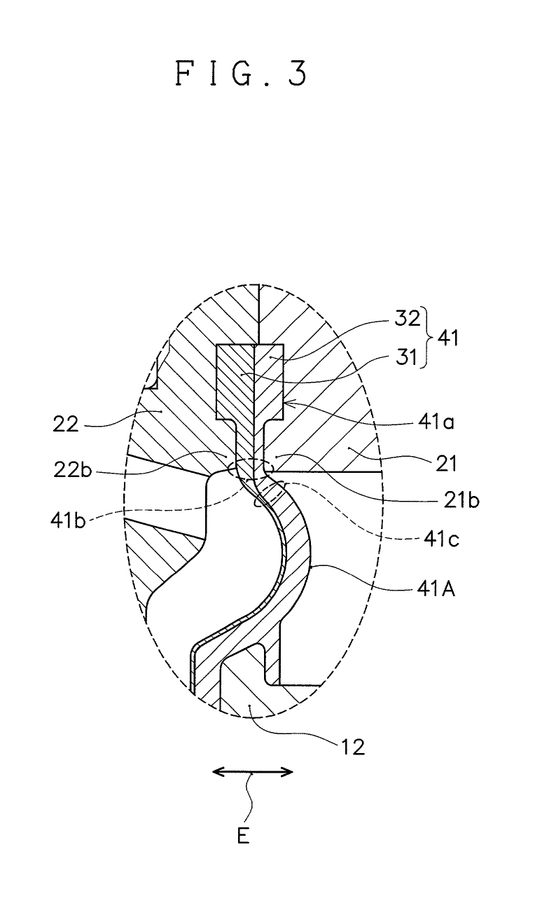

This embodiment has been described by taking an example where the dislocation of the bending portion from the clamp receiving portion is achieved through the adjustment of the thickness of the diaphragm in the reciprocating direction thereof. However, the present invention is not necessarily limited to this. Rather, various arrangements can be taken for the dislocation of the bending portion, as far as the clamp receiving portion attains a higher rigidity than the movable section. For example, the clamp receiving portion may be made of a material having a high rigidity. FIG. 3 illustrates an example for achieving the higher rigidity of the clamp receiving member. Specifically, FIG. 3 is an enlarged cross section illustrating the pump head and its proximity of the reciprocating pump according to another embodiment of the present invention, which portion corresponds to that of the embodiment illustrated in FIG. 2.

The reciprocating pump of this embodiment has basically the same arrangement as that of the first embodiment illustrated in FIGS. 1 and 2. The difference between two embodiments mainly presents in the arrangement of the diaphragm. Therefore, the description will hereinafter be made mainly for the features of the diaphragm illustrated in FIG. 3, so that the description for the corresponding or identical parts or members to those of the first embodiment will be omitted.

A diaphragm 41 as illustrated in FIG. 3 is integrally formed with a perimeter section 41a clamped between the fixed member 21 and the pressing member 22, and a movable section 41A capable of being moved under the operation of the piston unit 12. The diaphragm 41 is formed in a multi-layered structure with a first diaphragm layer 31 and a second diaphragm layer 32 deposited, both of which are deposited to each other in the reciprocating direction of the movable section 41A. The first diaphragm layer 31 is made of a material having a higher rigidity than the second diaphragm layer 32. As a material of the first diaphragm layer 31, PTFE, PFA, PE or the like may be used, while as the second diaphragm layer 32, rubber or the like may be used.

The diaphragm 41 of this embodiment is clamped into a fixed position by the fixed member 21 and the pressing member 22, as described above. Specifically, the perimeter section 41a and its periphery are clamped by using the fixed member 21 and the pressing member 22. A portion of the diaphragm 41 closer to the movable section 41A is fixed by the end portion 21b of the fixed member 21 and the end portion 22b of the pressing member 22. The portion which is claimed by the end portions 21b, 22b of the fixed member 21 and the pressing member 22 will be hereinafter referred to a clamp receiving portion 41b.

The diaphragm 41 of FIG. 3 is formed by the first and second diaphragm layers 31, 32 to have a double-layered structure with the clamp receiving portion 41b and the movable section 41A having a uniform thickness in the reciprocating direction of the diaphragm 41 or in the direction of arrow D in FIG. 5 and with at least one of the layers thereof having a thickness varied according to a position along the diaphragm. Specifically, the clamp receiving portion 41b has the first diaphragm layer 31 thicker than the second diaphragm layer 32, while the movable section 41A has the second diaphragm layer 32 thicker than the first diaphragm layer 31.

With the reciprocating pump using the diaphragm 41 having the above arrangement, the slurry can smoothly be transferred without causing the problems as mentioned above, and therefore the reciprocating pump can be effectively driven, as described above.

That is, in the conventional reciprocating pumps, there may cause the intrusion of the slurry into the interface between the diaphragm 101 and the pressing member 112 as a result of the repeated application of the bending stress on the clamp receiving portion 101b due to the reciprocal movement of the diaphragm 101, and also may cause the deterioration of the life of the diaphragm 101 and its associated parts due to amplified stress through the bending portion at the time of the reciprocal movement of the diaphragm 101, which bending portion is matched in position with or located closer to the clamped portion which is rigidly clamped for the leakage free arrangement (see FIG. 5). On the contrary, the diaphragm 41 in the reciprocating pump of this embodiment is unlikely to bend along the clamp receiving portion during the reciprocal movement of the piston unit 12 in the direction of arrow D, thus not causing such problems. The diaphragm 41 of the reciprocating pump according to this embodiment is reciprocally moved with a bending portion 41c closer to the movable section 41A than the clamp receiving portion 41b, along which the diaphragm 41 is bent.

The dislocation of the bending portion 41c from the clamp receiving portion 41b is accomplished by the adjustment of the thickness and rigidity of at least one of layers forming the diaphragm 41. Specifically, the diaphragm 41 has the clamp receiving portion 41b formed by the first diaphragm layer 31 having a larger proportion with respect to or being thicker than the second diaphragm layer 32, while maintaining an uniform thickness of the diaphragm. That is, the clamp receiving portion 41b which is made of a high rigid material possesses a higher rigidity than the bending portion 41c. The diaphragm 41 of this embodiment is thus driven, as repeatedly bending along the bending portion 41c dislocated from the clamp receiving portion 41b.

More specifically, according to the reciprocating pump of this embodiment with the diaphragm 41 having the clamp receiving portion 41b, which is unlikely to bend during the reciprocal movement of the diaphragm 41, there causes no clearance between the clamp receiving portion 41b and the pressing member 22. With the diaphragm 41 having this arrangement, the reciprocating pump can transfer the slurry through the reciprocal movement of the diaphragm 41 and more specifically the movable section 41A with no clearance as mentioned above, thereby effectively preventing the slurry from intruding into the interface between the clamp receiving portion 41b and the pressing member 22. As a result, excessive friction or any other undesirable effects due to the intrusion of the slurry is avoidable, the occurrence of cracks, ruptures and so on can be limited and hence an improved durability is attainable.

This embodiment has been described by taking for example the case where two different materials are used to form the diaphragm in a multi-layered structure. However, the present invention is not necessarily limited to this two-layered structure. Three or more layered structure formed with different materials may be employed to improve the rigidity of the clamp receiving portion according to a specific purpose.

This embodiment has also been described by taking for example the case where the diaphragm illustrated in FIGS. 2 and 3 is applied to the reciprocating pump for transferring the slurry. However, the present invention is not necessarily limited to this application. The diaphragm of the present invention may be mounted in the reciprocating pump for transferring varying fluid. In such a case, the desirable effects such as the improvement in durability of the diaphragm, as described above can also be produced.

The diaphragm of the present invention may be applied to a different field, such as a vibration plate mounted in a speaker or telephone set to produce the desirable effects as described above, that is, improved durability through dislocation of the bending portion from the clamp receiving portion.

This specification is by no means intended to restrict the present invention to the preferred embodiments set forth therein. Various modifications to the diaphragm and the reciprocating pump using the same, as described herein, may be made by those skilled in the art without departing from the spirit and scope of the present invention as defined in the appended claims.

What is claimed is:

1. A diaphragm integrally formed with a movable section and a perimeter section, said movable section adapted to be reciprocally moved, and said perimeter section extending around said movable section and shaped to provide a clamp receiving portion adapted to be clamped into a fixed position, wherein a bending portion along which said movable section is reciprocally moved with said clamp receiving portion clamped is located closer to said movable section than said clamp receiving portion of said perimeter section.

2. A diaphragm integrally formed with a movable section and a perimeter section used in a pump or the like for pumping fluid therethrough, said movable section adapted to be reciprocally moved for creating a pumping effect, and said perimeter section extending around said movable section and shaped to provide a clamp receiving portion adapted to be clamped into a fixed position, wherein a bending portion along which said movable section is reciprocally moved with said clamp receiving portion clamped is located closer to said movable section than said clamp receiving portion of said perimeter section.

3. A diaphragm according to claim 2, wherein said clamp receiving portion of said perimeter section is formed to have a higher rigidity than said bending portion.

4. A diaphragm according to claim 3, wherein said perimeter section is made of a material having a higher rigidity than said movable section.

5. A diaphragm according to claim 2, wherein said clamp receiving portion of said perimeter section is formed to be thicker in the reciprocating direction of said movable section than said bending portion.

6. A diaphragm according to claim 2, wherein said movable section and said perimeter section have a multi-layered structure with layers thereof deposited to each other in the reciprocating direction of the movable section, and wherein at least one of said layers is adjusted in rigidity so that the clamp receiving portion of the perimeter section has a higher rigidity than said bending portion.

7. A diaphragm according to claim 2, wherein said movable section and said perimeter section have a multi-layered structure with layers thereof deposited to each other in the reciprocating direction of the movable section, and wherein at least one of said layers is adjusted in thickness so that the clamp receiving portion of the perimeter section has a higher rigidity than said bending portion.

8. A diaphragm according to claim 2, wherein said movable section and said perimeter section have a multi-layered structure with layers thereof deposited to each other in the reciprocating direction of the movable section, and wherein at least one of said layers is adjusted in thickness so that the clamp receiving portion of the perimeter section is thicker than said bending portion.

9. A reciprocating pump for transferring slurry or the like comprising a reciprocally movable diaphragm, said diaphragm integrally formed with a movable section and a perimeter section, said movable section adapted to be reciprocally moved for creating a pumping effect, and said perimeter section extending around said movable section and shaped to provide a clamp receiving portion adapted to be clamped into a fixed position, a pressing member and a fixed member both being cooperated with each other to clamp said clamp receiving portion of said perimeter section into a fixed position, wherein a bending portion, along which said movable section is reciprocally moved with said clamp receiving portion clamped between said pressing member and said fixed member, is located closer to said movable section than said clamp receiving portion of said perimeter section.

10. A reciprocating pump according to claim 9 being constructed by using a diaphragm according to any one of claims 3 to 8.
